(19) United States
(12) Patent Application Publication
(10) Pub. No.: US 2015/0188002 A1
(43) Pub. Date: Jul. 2, 2015

(54) LIGHT EMITTING DEVICES HAVING RARE EARTH AND TRANSITION METAL ACTIVATED PHOSPHORS AND APPLICATIONS THEREOF

(71) Applicant: AUTERRA, INC., SCHENECTADY, NY (US)

(72) Inventor: PARTHA S. DUTTA, CLIFTON PARK, NY (US)

(21) Appl. No.: 14/644,734

(22) Filed: Mar. 11, 2015

Related U.S. Application Data
(63) Continuation-in-part of application No. 14/521,980, filed on Oct. 23, 2014.
Application No. 14/521,980 is a continuation of application No. 13/293,581, filed on Nov. 10, 2011, now Pat. No. 8,974,695.
(60) Provisional application No. 61/412,650, filed on Nov. 11, 2010.

(51) Int. Cl. H01L 33/50; H01L 33/32; C09K 11/77

(52) U.S. Cl. CPC H01L 33/504; C09K 11/7733; H01L 33/32

(57) ABSTRACT

Light emitting devices and applications thereof. The light emitting devices include a light emitting device having an active layer of a semi-conductor and a phosphor having the general formula Ca₁₊ₓSr₁₋ₓGa_{y}In_{2-y}S_{z}Se_{3-z}F₂, wherein 0≦x≦1, 0≦y≦2 and 0≦z≦3. The phosphors are activated with an activator which may include dopants such as europium (Eu), cerium (Ce), praseodymium (Pr), terbium (Tb), ruthenium (Ru), erbium (Er), manganese (Mn) and mixtures thereof.

### CROSS-REFERENCE TO RELATED APPLICATIONS

This application is a continuation-in-part application claiming the priority and benefit of U.S. application Ser. No. 14/521,980, filed Oct. 23, 2014, entitled “Phosphors of rare earth and transition metal doped Ca₁₊ₓSr₁₋ₓGa_{y}In_{2-y}S_{z}Se_{3-z}F₂ wherein 0≦x≦1, 0≦y≦2 and 0≦z≦3; methods of manufacturing and applications,” which claims priority and benefit to U.S. application Ser. No. 13/293,581, filed on Nov. 10, 2011, which claims the priority and benefit of Provisional Application No. 61/412,650, filed Nov. 11, 2010, the disclosures of which are hereby incorporated herein by reference.

### BACKGROUND

Solid state lighting (SSL) technologies based on light emitting diodes (LEDs) are promising for a number of applications including general illumination, displays, medical systems, communication systems, etc. Significant growth in the SSL industry will be based on the availability of high efficiency, high power white LEDs. Currently available commercial white LEDs especially for warm white are not quite satisfactory for most general illumination applications. Their overall light output, luminous efficacy, color properties, and life must improve and the cost must be reduced before white LEDs can experience widespread usage in general lighting applications. Two popular methods for creating white light sources are (a) using phosphor based wavelength conversion structures and (b) using mixed color LEDs (red, blue and green referred to as RGB).

Both of these methods have their own advantages. The RGB based white LEDs offers the capability to tune colors in real time and may better color properties in display applications. On the other hand, RGB white light LED systems require sophisticated active feedback control to keep the light at a stable color because the red, green and blue LEDs are created from different semiconductor materials. Currently the overall efficiency of RGB lighting system is low mainly due to low quantum efficiency of gallium indium nitride direct emission green LEDs with peak emission wavelength near 555 nm (the peak of the human eye sensitivity). This is referred to as the “green gap” in the industry. To achieve high luminous efficacy for mixed color LEDs, the external quantum efficiency (EQE) of green LEDs needs to improve significantly. However, there are fundamental material challenges due to which high EQE for epitaxially grown Ga₁₋ₓInₓN based direct emission green LEDs has not been achieved to-date.

Phosphor-converted white light-emitting diodes (PC-LED) are rapidly progressing to meet the solid-state lighting goals of 200 lumens per watt (lm/W) by 2020 set by the United States Department of Energy (U.S. DOE). Presently available commercial white LEDs are delivering about 100 lumens per watt. However to reach 200 lm/W, significant improvements are needed at several stages, including internal quantum efficiency, extraction efficiency from the chip, and phosphor system efficiency, which includes phosphor conversion efficiency and extraction efficiency at the LED package level. Hybrid approaches for white light sources also have potential for general illumination purposes. In this approach, LEDs of individual wavelengths (red, blue, green, yellow, amber, etc.) with the highest efficiencies are integrated into a system to provide color mixing. The individual wavelength LEDs may be either direct emission LEDs or PC-LEDs. In this regard, higher efficiency PC-LEDs for green emission wavelengths (in the green-gap) are better suited than the low efficiency direct emission green LEDs.

For display applications such as the Liquid Crystal Displays (LCD), LED based backlighting are anticipated to provide a superior color gamut compared to the existing cold cathode fluorescent lamp (CCFL). Numerous benefits for LED backlighting lighting for LCD displays include: no mercury, much longer source life, greater than 30,000 hours, compared to CCFL, and LEDs are less prone to breaking. However, presently LED based displays are less energy efficient and higher in cost compared to CCFL based displays. Apart from the traditional general illumination and display technologies, there is a vast commercial market for LED based light sources with different emission wavelengths. Applications in biotechnology, indoor agriculture, photo-chemical reactions, adaptive illumination, photo-therapy, data communication, etc. are just a few examples.

For solid state light sources to be feasible for large scale deployment, there are few criteria that needs to be satisfied: higher wall plug efficiencies, low cost, availability of light sources with a variety of spectral content, ease of manufacturing and integration within systems, etc. Availability of light sources with any desirable peak emission wavelengths across the visible light spectrum will be necessary for a multitude of future applications. While direct emission LEDs based on semiconductor p-n junction diodes are available for discrete wavelengths, developing the technologies for high efficiency devices for a large number of emission wavelengths is not feasible. For direct emission LED development for any new emission wavelength, long term (5-10 years) and huge investments are necessary. In addition, integration and active control of large number of direct emission LEDs in a high efficacy light source is problematic and would be cost prohibitive as well as consume higher power during operation.

PC-LEDs are an attractive proposition since development of high efficiency phosphors of various emission wavelengths can be done simultaneously (short time period) with relatively low investments. Using the blue or ultraviolet (UV) direct emission gallium indium nitride and aluminum gallium nitride LEDs as excitation source for phosphors, PC-LEDs with large number of emission wavelengths may be developed. PC-LEDs also offer tremendous opportunities due to their simplicity and lower cost of fabrication, tunable and wide spectral characteristics, low power consumption and ease of operation, etc. Due to these reasons, intense research is being conducted world-wide in the area of down conversion phosphors that may be excited by blue LEDs.

High efficiency phosphors compounds have been studied extensively and sufficiently developed for UV excitation such as used in existing CFL (compact fluorescent lamp), CRT (cathode ray tube), CCFL (cold cathode fluorescent lamp), etc. However these phosphors have poor absorption and wavelength conversion efficiencies for excitation sources in the blue region of the visible spectrum (400-480 nm). Current research in new phosphor compounds is targeted towards the development of materials that possess high absorption coefficient for blue wavelengths and high quantum efficiencies for converting blue to longer wavelength photons. Rigorous search for high efficiency phosphor materials and unique composition of matter continues at the present time. Some of the high efficiency phosphor compounds found to-date are discussed below.

Phosphor-converted white LEDs are commonly achieved by using a yellow phosphor with a blue LED or by using red, green, blue (RGB) phosphors with a UV LED. One of the most popular yellow phosphors presently used in commercial white LEDs is Y₃Al₅O₁₂:Ce³⁺ (YAG:Ce). Since the successful development of Ga₁₋ₓInₓN blue LEDs, researchers have investigated four broad categories of high efficiency phosphors for white LED applications with various degrees of success. These high phosphors falls in the following categories: (i) metal oxides, (ii) metal sulfides, selenides and thiogallates, (iii) metal nitrides and (iv) metal oxo-nitrides. Some of these high efficiency blue wavelength excitable phosphors with emission peak tunable across the visible spectrum are already being used in white LED fabrication. The chemical compositions of these phosphors are listed below:

Yttrium aluminum garnet family: (YₓGd₁₋ₓ)₃(Al_{y}Ga_{1-y})₅O₁₂:Ce³⁺, Pr³⁺ with 0<x<1.

Silicate garnet family: ML₂QR₄O₁₂:Ce³⁺, Eu³⁺. Here M is elements from the group IIA (Mg, Ca, Sr, Ba). L may be rare earth elements from the group consisting of Sc, Y, La, Ce, Pr, Nd, Pm, Sm, Eu, Gd, Tb, Dy, Ho, Er, Tm, Yb and Lu. Q may be elements from the group IVA (Si, Ge, Sn, Pb). R may be elements from the group IIIA (B, Al, Ga, In, Tl).

Vanadate garnet family: Ca₂NaMg₂V₃O₁₂:Eu³⁺.

Mixed oxides family: (Y_{2-x-y}EuₓBi_{y})O₃:Eu³⁺, Na₂Gd₂B₂O₇:Ce³⁺, Tb³⁺, YCa₃M₃B₄O₁₅:Eu³⁺ where M may be elements from group IIIA (Al, Ga, In), LaCeSr₂AlO₅:Ce³⁺, Ba₂Al₂O₄:Eu²⁺.

Alkaline earth metal silicates family: (Ba_{1-x-y}SrₓCa_{y})SiO₄:Eu⁺ series such as Ca₃MgSi₂O₈:Eu²⁺, Sr₃MgSi₂O₈:Eu²⁺, Ba3MgSi2O8:Eu2+, and their mixtures; Ba₂MgZnSi₂O₄:Eu²⁺, Sr₃SiO₅:Eu²⁺, Li²SrSiO⁴:Eu²⁺, and A₂SiO₄:Eu²⁺, D where A is elements from group II (Sr, Ba,Ca,Zn,Cd,Mg) and D is elements such as F,Cl,Br,I,N,S,P.

Alkaline earth metal sulfides and selenides, MS: Eu²⁺ and MSe: Eu²⁺. Here M is elements from group IIA (Mg, Ca, Sr, Ba) such as Ca₁₋ₓSrₓS:Eu²⁺, Ca₁₋ₓSrₓSe:Eu²⁺, Ca₁₋ₓSrₓS_{y}Se_{1-y}:Eu²⁺ with 0<x<1 and 0, y<1.

Alkaline earth metal thiogallates: metal sulfide thiogallates such as (SrMgCaBa)(GaAlIn)₂S₄:Eu²⁺ and metal sulfo-selenide thiogallates such as MA₂(SₓSe_{y})₄:B; MA₄(SₓSe_{y})₇:B; M₂A₄(SₓSe_{y})₇:B; (M1)ₘ(M2)ₙAₚ(SₓSe_{y})_{q}; where M=Be,Mg,Ca,Sr,Ba,Zn; M1=Be,Mg,Ca,Sr,Ba,Zn; M2=Be,Mg,Ca,Sr,Ba,Zn; A=Al,Ga,In,Y,La,Gd; B=Eu,Ce,Cu,Ag,Al,Tb,Cl,Br,F,I,Mg,Pr,K,Na,Mn. The range of compositions covered for high efficiency sulfo-selenide thiogallate phosphors are as follows: m=0 to 1; n=0 to 1; m+n=1 (close to 1); p=close to 2 or close to 4; q=close to 4 or close to 7; when p=close to 2, q=close to 4; when p=close to 4, q=close to 7; x=0 to 1; y=0 to 1; x+y=0.75 to 1.25; x+y=0.5 to 1.5; B=0.0001 to 10 mole %.

Metal nitrides family: MₓSi_{y}N_{z}:Eu²⁺, Ce³⁺ where M=Mg, Ca, Sr, Ba, Ln, Y, Yb, Al such as Sr₂Si₅N₈:Eu²⁺, Ba₂Si₅N₈:Eu²⁺, (Sr_{1-x-y}BaₓCa_{y})₂Si₅N₈:Eu²⁺, CaAlSiN₃:Eu²⁺, CaₓAl_{y}Si_{z}N₃:Ce³⁺, CaSiN₂:Ce³⁺.

Metal oxo-nitrides family: MSi₂O₂N₂:Eu²⁺ where M=Ba, Sr, Ca, etc., (SrCa)_{p/2}Al_{p+q}Si_{12-p-q}O_{q}N_{16-q}:Eu²⁺, (CaₓM_{y})(Si,Al)₁₂(O,N)₁₆:Eu²⁺ where M=Eu,Tb,Yb,Er group element, LiₓM_{y}Ln_{z}Si₁₂₋₍ₘ₊ₙ₎Al₍ₘ₊ₙ₎OₙN₁₆₋ₙ:Eu²⁺ where M=Ca, Mg, Y and Ln=Eu, Dy, Er, Tb, Yb, Ce, SrSiAl₂O₃N₂:Eu²⁺.

According to the US Department of Energy (DOE) roadmap for phosphor development targets for 2015 including a quantum yield of 90% across the entire visible spectrum, color uniformity, color stability, thermal sensitivity and reduced optical scattering require the search for new phosphor materials and/or fine tuning the compositions of known phosphors. Therefore, a need exists for synthesizing selective crystalline phases of various alloy systems that have higher quantum conversion efficiencies and performance characteristics suitable for device fabrication and operation. Further, a need exists for new alloy compositions that have been demonstrated to yield high wall plug efficiency and high efficacy light sources.

### BRIEF DESCRIPTION OF THE DRAWINGS

The disclosure itself will be best understood by reference to the following detailed description of illustrative embodiments when read in conjunction with the accompanying drawings, wherein:

FIG. 1 shows a typical PC-LED structure excited by a blue or UV LED;

FIG. 2a shows the PL spectrum of the phosphor (solid curve) in Example 1 and (dashed curve) in Example 2;

FIG. 2b shows the PL spectrum of the phosphor in Example 3;

FIG. 2c shows the PL spectrum of the phosphor in Example 4;

FIG. 2d shows the PL spectrum of the phosphor in Example 5;

FIG. 3 shows the powder XRD of the phosphor in Example 1;

FIG. 4 depicts an embodiment of a lead type light emitting diode (LED);

FIG. 5 depicts an embodiment of a tip type (LED);

FIG. 6 depicts a block diagram of an embodiment of a display device;

FIG. 7a depicts a schematic sectional view of an embodiment of a planar light source;

FIG. 7b depicts a schematic sectional view of an alternative embodiment of a planar light source;

FIG. 7c depicts a schematic sectional view of another alternative embodiment of a planar light source;

FIG. 8 depicts a plain view of an embodiment of an LED display device;

FIG. 9 depicts a plain view of an alternative embodiment of an LED display device; and

FIG. 10 depicts a chromaticity diagram of an alternative embodiment of a light emitting device having two or more phosphors.

### SUMMARY

A first aspect of the present disclosure is a light emitting device comprising a light emitting component having an active layer comprising a semi-conductor material, a phosphor having a general formula Ca1+xSr1−xGayIn2-ySzSe3−zF2, wherein 0≦x≦1, 0≦y≦2 and 0≦z≦3 and an activator of the phosphor, wherein an emission spectrum of light emitted from the light emitting component excites the phosphor and the activator.

A second aspect of the present disclosure is a method for emitting white colored light from a light emitting device comprising the steps of providing the light emitting device having a light emitting component with an active layer comprising a semi-conductor material, emitting a blue or ultraviolet light from the light emitting component, providing a phosphor having a general formula Ca₁₊ₓSr₁₋ₓGa_{y}In_{2-y}S_{z}Se_{3-z}F₂, wherein 0≦x≦1, 0≦y≦2 and 0≦z≦3, activating the phosphor with an activator selected from the group consisting of elemental forms of europium (Eu), cerium (Ce), praseodymium (Pr), terbium (Tb), ruthenium (Ru), erbium (Er), manganese (Mn), ionic forms thereof and mixtures thereof, absorbing part of the blue or ultraviolet light by the activated phosphor and emitting from the activated phosphor a spectrum of light that provides white light.

### DETAILED DESCRIPTION

The present disclosure provides rare earth and/or transition metal doped Ca₁₊ₓSr₁₋ₓGa_{y}In_{2-y}SzSe_{3-z}F₂ (0≦x≦1, 0≦y≦2, 0≦z≦3, particularly 0<x<1, 0<y<2, 0<z<3) compounds, phosphors or alloys, that may be used for photon energy down conversion applications. The rare earth and/or transition metal impurities used as dopants/activators include, but are not limited to, Eu, Ce, Pr, Tb, Ru, Er, Mn, ionic forms thereof and and/or mixtures thereof. These alloys may absorb photons of higher energy and emit photons of lower energy. For example, the alloy can absorb UV or blue or green wavelength photons and emit green or yellow or red wavelength photons. The absorption characteristics of the phosphor can be tuned by the chemical composition of the alloy. The emission characteristics of the phosphor can be tuned by the chemical composition of the alloy and the activator species. The quantum efficiency of the alloy is decided by the crystalline phase and the defects in the material. Defects include bulk point defects, bulk extended defects and surface defects such as dangling bonds.

Solid state light emitting devices currently available, including LED based light emitting devices, do not meet or exceed the desired criteria for large scale deployment, including higher wall plug efficiencies, low cost, availability of light sources with a variety of spectral content, and simplified manufacturing and integration within existing systems. Nor do currently available solid state light emitting devices meet the US D.O.E's goals of a 90% quantum yield of across the entire visible spectrum, color uniformity, color stability, thermal sensitivity and reduced optical scattering. The phosphor compositions and their applications described below meet these goals while and providing a better quality light source for large scale development, that is low cost and simple to manufacture.

The dopants/activators may be present in minute quantities for emission of low energy photons by absorbing higher energy photons. Generally, the activator/dopant may be present in an amount in the range of from about 0.001 mol % to about 10 mol %. The alloy composition represented by x, y and z, the dopant species and the dopant concentrations are selected to tune the position and width of the emission peak.

Examples of alloy compositions in accordance with the present disclosure include, but are not limited to, Ca₂Ga₂S₃F₂, CaSrGa₂SSe₂F₂, CaSrGaInSe₃F₂, CaSrGa₂S₃F₂, Ca₂Ga₂SSe₂F₂, and/or mixtures thereof. In particular, Eu²⁺ doped CaSrGa₂SSe₂F₂ with a peak emission wavelength in the range of from about 540 nm to about 600 nm and Eu²⁺ doped Ca₂Ga₂SSe₂F₂ with peak emission wavelength in the range of from about 540 to about 600 nm are may be preferred in some instances. An Eu⁺² doped phosphor composition having the formula CaSrGa₂SSe₂F₂ may have a peak emission wavelength of about 550 nm. An Eu⁺² doped phosphor having the formula Ca₂Ga₂SSe₂F₂ may have a peak emission wavelength of about 600 nm. The subscripts in each example represent the mole fractions of the elements present in the compound.

The use of group II, III, VI and VII elements other than Ca, Sr, Ga, In, S, Se, and F, such as Mg, Ba, Zn, Cd, Al, O, Te, Cl, and/or mixtures thereof, may either result in poor quantum efficiency or high moisture sensitivity of the phosphor powder. Crucial performance characteristics of phosphors include: (a) degradation of output lumens under actual operating conditions (continuous illumination), (b) quantum efficiency at higher operating temperatures (typically encountered during LED operations), (c) shift in peak emission wavelength at operating temperature, (d) optical absorption coefficient for the higher energy photons used for excitation, (e) optical transparency of phosphor for the emission wavelength, (f) easy to handle during device fabrication and integration into passive and active structures, and (g) cost of manufactured product suitable for applications. Satisfying these stringent performance criteria requires careful optimization of the alloy composition and the synthesis process.

In the present disclosure, we have used a multi-step synthesis process to systematically alter the compositions and study the effect of alloy composition on the quantum conversion efficiencies. It has been observed that even though the peak emission of a specific alloy system activated with a specific dopant remains the same, light emission properties such as quantum conversion efficiency, wall plug efficiency of the device, the emission peak width, the output lumens with time for continuously operated devices may be dependent on the crystalline phase and/or elemental ratios in the alloy.

A method of synthesis of the composition of the present disclosure is also disclosed using Ca, Sr, Ga, In, S, and Se elements wherein at least one of the elements is in a fluoride compound, such as calcium fluoride (CaF), and one or more dopant/activator impurities are selected from the group consisting of rare earth metals, transition metals and/or mixtures thereof is disclosed. Synthesis methods for use in the present disclosure include, but are not limited to, synthesis in a single pot from a high temperature melt (liquid phase); synthesis in a single pot by solid state reaction process; and synthesis in a single pot by exposing a liquid of selected elements to the vapor of other reactant elements. Other crystalline synthesis methods as would be known by those skilled in the art may be used.

Generally, the procedure for synthesis and characterization of the disclosed phosphor class comprises the following sequential steps:

Reactants in elemental or compound form may be mixed together at room temperature into a homogeneous powder form. The reactants mixed in this step may depend on the process used for high temperature reaction in subsequent steps. For example, if a vapor phase reaction is used, only a sub-set of the reactants are mixed together at room temperature. The remaining reactants are mixed at high temperature from vapor phase.

Suitable reactants include, but are not limited to, elemental reactants (Ca, Ga, Sr, S, Se), compounds Sr(OH)₂, SrCO₃, SrCl₂, SrO, SrF₂, CaO, CaF₂, Ga₂O₃, GaCl₃, GaS, GaSe, CaS, SrS, SrSe, EuCl₃, Er₂O₃, EuF₂, CeCl₃, and/or mixtures thereof.

The homogeneous powder is reacted inside a high temperature furnace under vacuum or inert gas ambient. The ambient plays an important role on the surface chemical composition of the reacted alloy which in turn impacts the performance characteristics of the phosphor.

Reacted alloy is grounded into a fine powder and homogenized thoroughly at room temperature.

The homogeneous powder is then annealed at high temperature under vacuum or inert gas ambient. The purpose of this step is multi-fold: (a) to selectively evaporate and eliminate un-reacted species from the powder, (b) to selectively tune the surface alloy composition by decomposing a sub-set of the compounds present, (c) to homogenize the spatial chemical composition across each crystallite in the powder, (d) to grow the size of high quality crystallites from previously present nuclei, (e) to alter the crystallographic phase of the alloy, (f) to modify the morphology of the crystallites present in the powder, (g) to relieve the stress in the crystallites created during the grinding process, (h) to eliminate point and extended defects present in the crystallites, (i) to perform surface passivation of dangling bonds, and (j) to effectively activate the dopant species.

The annealed powder is then grinded finely and chemically washed to clean the surface and expose the high quality/pristine surface of the crystallites. Selection of chemicals is made to avoid degradation of the crystal structure or significant alteration of the chemical composition of the alloy. The phosphor particle/crystal extraction may use selective chemical etching solutions. Generally, the chemical etching solution has a pH in the range of from about 8 to about 12 and comprises water and a base, including but not limited to, KOH, NaOH, NH₄OH, and/or mixtures thereof.

The chemically treated powder is transferred to a storage medium such as an organic solution to avoid exposure to moisture and air.

The powder is dried under inert gas or vacuum or directly transferred to an epoxy mixture for fabricating the wavelength conversion device. Dried powders are also used for a variety of chemical, micro-structural and crystallographic characterizations using energy dispersive x-ray analysis (EDX), secondary electron microscopy (SEM), transmission electron microscopy (TEM), powder x-ray diffraction (XRD), surface x-ray photoelectron spectroscopy (XPS), and particle size analysis using photon correlation spectroscopy (PCS).

For the optical characterization and device fabrication, thin solid films may be formed by mixing the phosphor powder with an epoxy (typically used for forming the optical dome on LED devices for light extraction) and coated on a glass plate. The epoxy-phosphor mixture may be baked around 80° C. under nitrogen or argon gas flow to form a solid film. The solid film may be characterized for its optical properties. Characterization techniques include photoluminescence spectroscopy (PL) and absorption spectroscopy (ABS).

The following non-limiting examples illustrate certain aspects of the present disclosure.

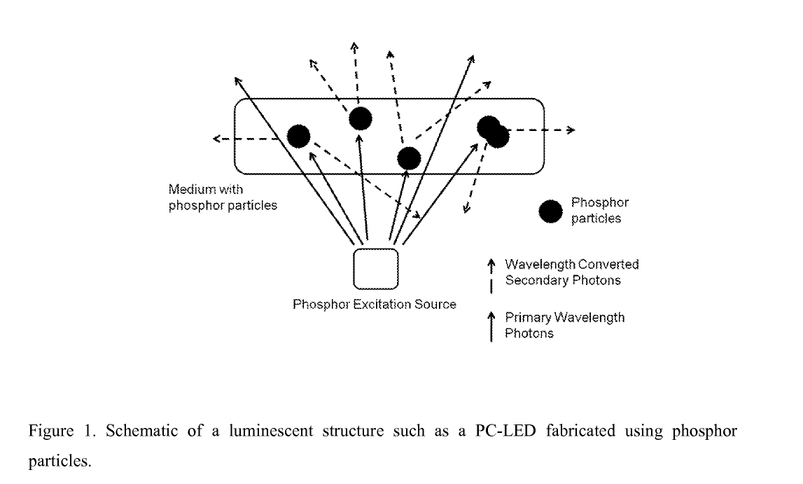

For PC-LED characterization, wall plug efficiency may be measured. FIG. 1 shows a typical PC-LED structure excited by a blue or UV LED. A blue LED (excitation wavelength: 451 nm) is used.

The examples below exemplify the role of alloy compositions, which may be used as phosphors, on the emission wavelength and final device performance. The present disclosure is not restricted to either wavelength range or device performance quoted herein. Compositions resulting in bluish green to red emission may be obtained by a variation of Ca₁₊ₓSr₁₋ₓGayIn_{2-y}S_{z}Se_{3-z}F₂ (0≦x≦1, 0≦y≦2, 0≦z≦3) doped with impurities such as Eu, Ce, Tb, Yb, Mn, and/or mixtures thereof.

### Example 1

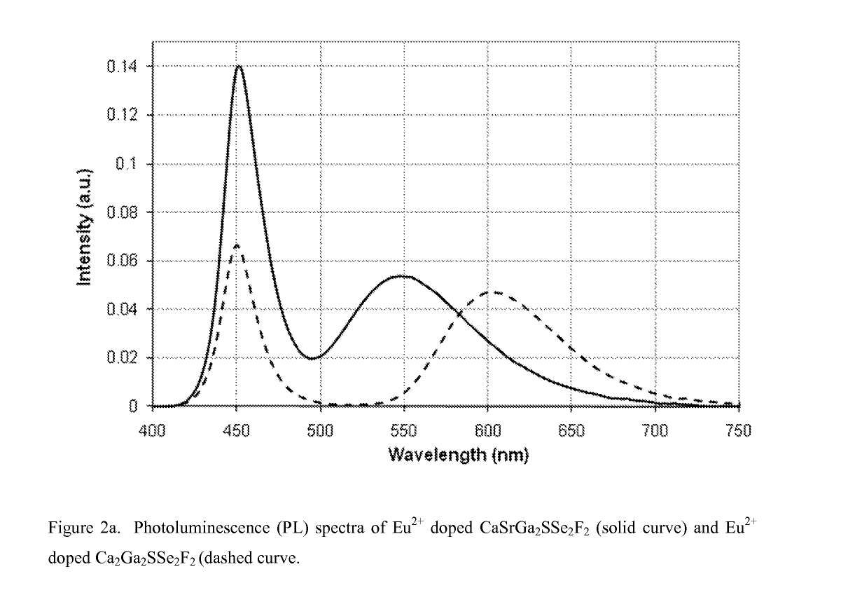

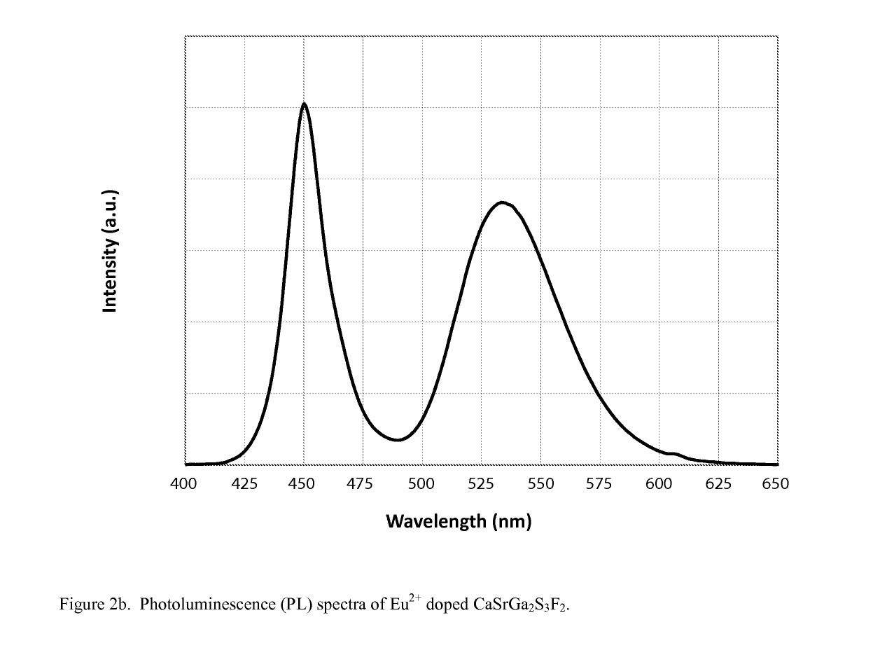

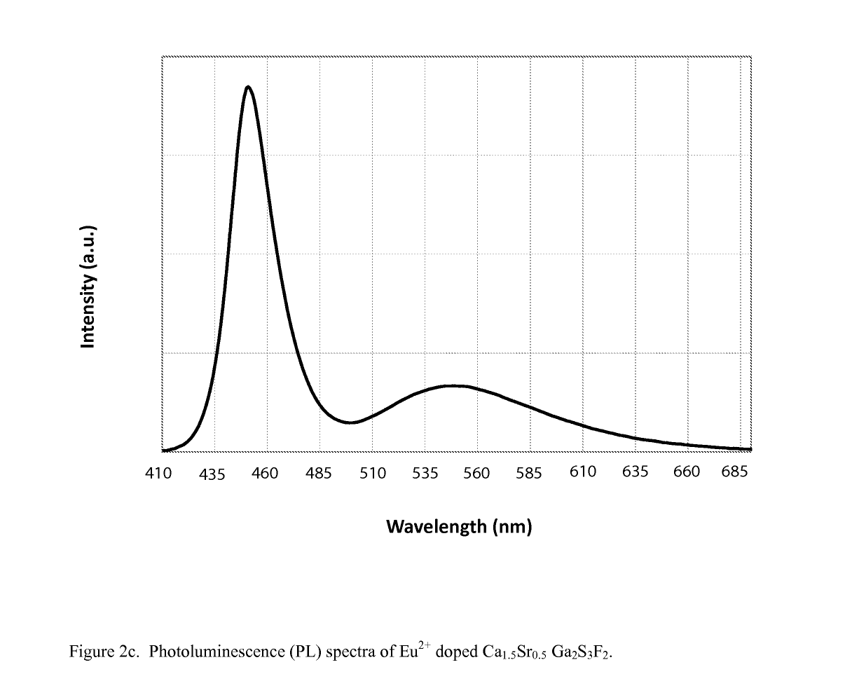

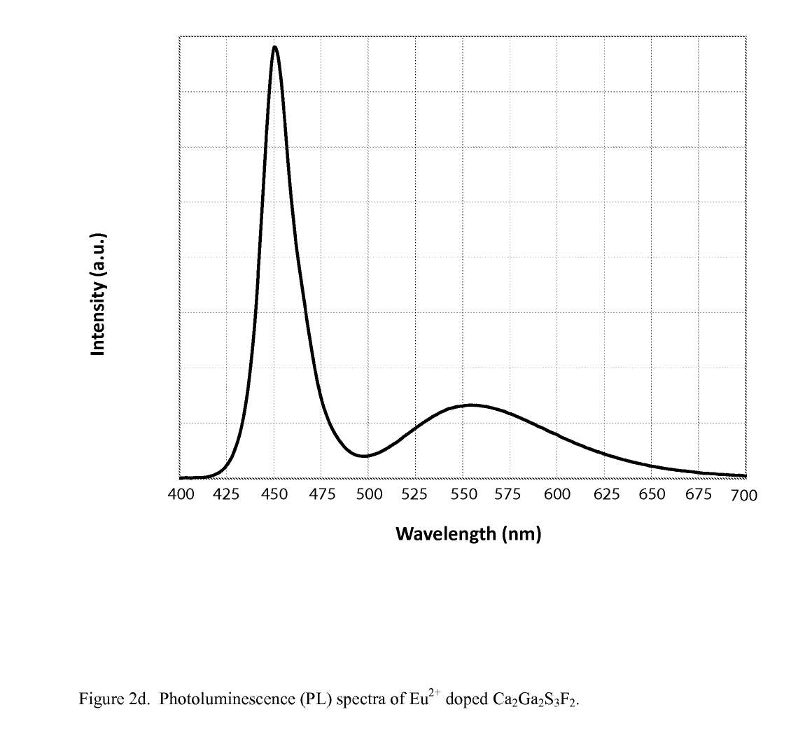

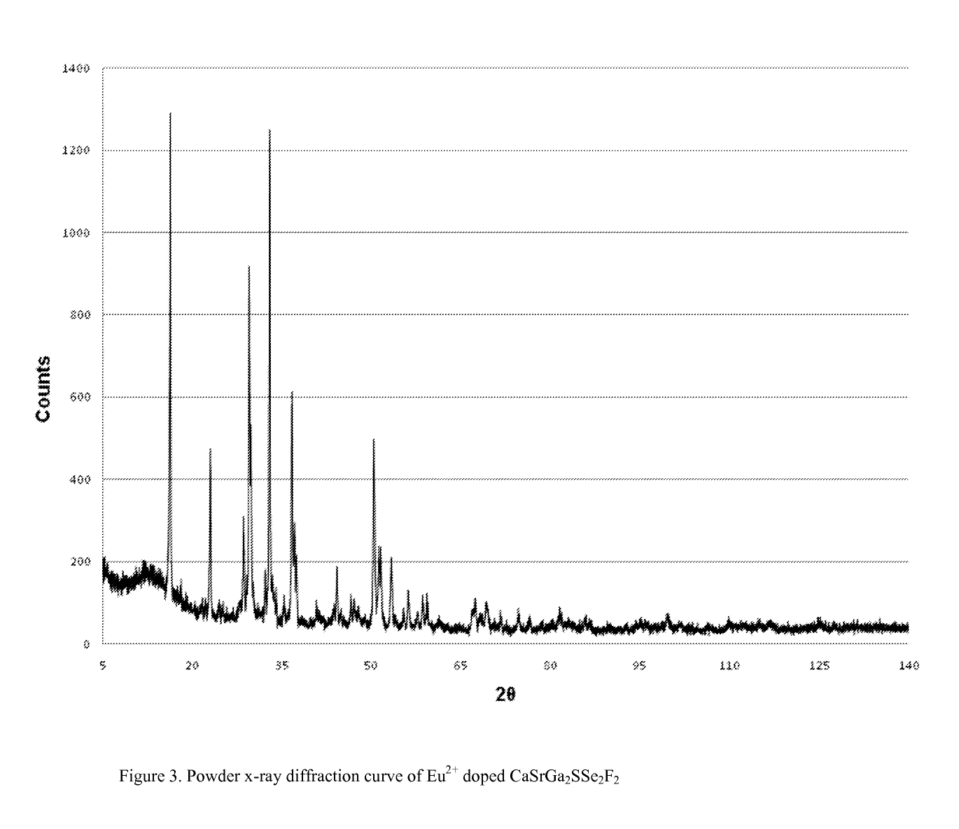

Eu²⁺ doped CaSrGa₂SSe₂F2 may be synthesized by reacting pre-synthesized SrSe, GaSe, GaS, CaF₂, and EuCl₃. One mole fraction of each compound (SrSe, GaSe, GaS, CaF₂) may be used. The EuCl₃ may be 4 weight % of the total weight of other compounds. The mixture is reacted at a temperature of 1000° C. under argon ambient for a period of 2 hours. A yellow green luminescent ingot is obtained. The ingot is crushed into a fine powder and re-annealed at a temperature of 850° C. under hydrogen ambient for a period of 30 minutes to obtain a yellow green luminescent free flowing powder. The powder is chemically washed in a KOH-water solution (pH in the range of 9-10) and dried with nitrogen gas. The PL spectrum of the phosphor is shown in FIG. 2a (solid curve). The powder XRD of the phosphor is shown in FIG. 3. The wall plug efficiency of the PC-LED fabricated using the dried powder and excited by blue LED (451 nm) is measured to be about 117-121 lumens/watt.

### Example 2

To demonstrate the peak emission tunability of the alloy composition of the present disclosure as a function of elemental ratios, Eu²⁺ doped Ca₂Ga₂SSe₂F₂ is synthesized by reacting pre-synthesized CaS, GaSe, CaF₂, and EuCl₃. One mole fraction of each compound CaS and CaF₂ is taken. Two mole fractions of GaSe are used. The EuCl₃ is 4 weight % of the total weight of other compounds. The mixture is reacted at a temperature of 1000° C. under argon ambient for a period of 2 hours. A yellow orange luminescent ingot is obtained. The ingot is crushed into a fine powder and re-annealed at a temperature of 850° C. under hydrogen ambient for a period of 30 minutes to obtain a yellow orange luminescent free flowing powder. The powder is chemically washed in a KOH-water solution (pH in the range of 9-10) and dried with nitrogen gas. The PL spectrum of the phosphor is shown in FIG. 2a (dashed curve).

### Example 3

Eu²⁺ doped CaSrGa²S³F² is synthesized by reacting pre-synthesized SrS:Eu²⁺, GaS and CaF². One mole fraction of SrS:Eu²⁺ and CaF₂ and eight moles (excess) of GaS are used. The Eu₂₊ is 2 weight % of the total weight of SrS in the synthesized compound. The mixture is reacted at a temperature of 900° C. under argon ambient for a period of 48 hours, followed by reacting at 1050° C. for 12 hours. The reaction mixture is cooled slowly at a rate of 2° C. per hour to a temperature of 950° C., followed by a rapid cooling cycle to room temperature at a rate of 50° C. per hour. Crystallites of green luminescence are obtained embedded in excess of GaS. The crystallites are extracted by washing the reacted mixture in KOH-water mixture (pH: 10-11) for a period of 12 hours. The extracted crystallites are crushed into a fine powder and re-annealed at a temperature of 900° C. under argon ambient for a period of 12 hours to obtain a green luminescent free flowing powder. The PL spectrum of the phosphor exhibits a broad peak around 530 nm when excited by a blue LED (451 nm) as shown in FIG. 2b.

### Example 4

Eu²⁺ doped Ca_{1.5}Sr_{0.5} Ga₂S₃F₂ is synthesized by reacting pre-synthesized SrS:Eu²⁺, CaS:Eu²⁺, GaS and CaF². One mole fraction of CaS:Eu²⁺ and CaF², one-half mole fraction of SrS:Eu²⁺ and eight moles (excess) of GaS are used. The Eu²⁺ is 2 weight % of the total weight of SrS and CaS in the synthesized compound. The mixture is reacted at a temperature of 850° C. under argon ambient for a period of 48 hours, followed by reacting at 950° C. for 24 hours. The reaction mixture is cooled slowly at a rate of 2° C. per hour to a temperature of 900° C., followed by a rapid cooling cycle to room temperature at a rate of 50° C. per hour. Crystallites of greenish yellow luminescence are obtained embedded in excess of GaS. The crystallites are extracted by washing the reacted mixture in mild KOH-water mixture (pH: 8-9) for a period of 36 hours. The extracted crystallites are crushed into a fine powder and re-annealed at a temperature of 850° C. under argon ambient for a period of 24 hours to obtain a greenish yellow luminescent free flowing powder. The PL spectrum of the phosphor exhibits a broad peak around 545 nm when excited by a blue LED (451 nm) as shown in FIG. 2c.

### Example 5

Eu²⁺ doped Ca₂Ga₂S₃F₂ is synthesized by reacting pre-synthesized CaS:Eu²⁺, GaS and CaF₂. One mole fraction of CaS:Eu²⁺ and CaF₂ and two moles of GaS are used. The Eu²⁺ is 2 weight % of the total weight of CaS. The mixture is reacted at a temperature of 1000° C. under argon ambient for a period of 24 hours. Large particulates of yellow luminescence are obtained. The particulates are crushed into a fine powder and re-annealed at a temperature of 850° C. under argon ambient for a period of 12 hours to obtain a yellow luminescent free flowing powder. The PL spectrum of the phosphor exhibited a broad peak around 555 nm when excited by a blue LED (451 nm) as shown in FIG. 2d.

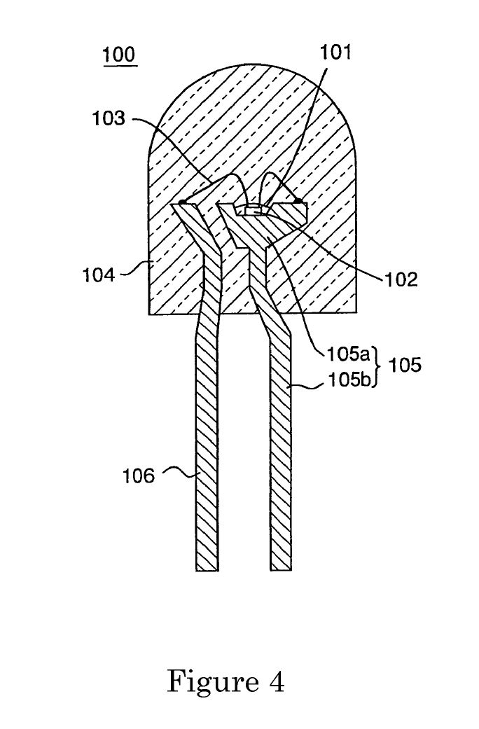

In some embodiments, the phosphors described above may be incorporated into a light emitting device as a light emitting diode 100 as shown in the embodiment depicted in FIG. 4. In the embodiment 100, the light emitting diode depicted is a lead type light emitting diode which may have a mount lead 105 and an inner lead 106. In some embodiments, the light emitting component may include a light emitting component 102 which may be installed on a cup 105a of the mount lead 105. Embodiments of the cup 105a may be filled with a coating resin 101 which may contain a phosphor that may cover the light emitting component 102 and is molded in resin. In some embodiments, an n electrode and a p electrode of the light emitting component 102 may be connected to the mount lead 105 and the inner lead 106, respectively, by means of wires 103.

In embodiments of the lead mounted light emitting diode described above, a portion of the light emitted by the light emitting component 102, for instance by an LED chip (hereinafter referred to as LED light) may excite the phosphor contained in the coating resin 101 to generate fluorescent light having a wavelength different from that of the LED light. In such an embodiment, the fluorescent light emitted by the phosphor and LED light, which is transmitted through the body 104 without contributing to the excitation of the phosphor, may be mixed and emitted out of the LED package 100. As a result, the light emitting device, such as the light emitting diode 100 outputs light having a spectrum different from that of LED light emitted by the light emitting component 102.

In alternative embodiments, a chip type light emitting diode 200 may be used, wherein a light emitting diode (LED chip) 202 may be installed in a recess of a casing 204. The recess of the casing may be filled with a coating material which contains a phosphor, such as the phosphors described above, to form a coating 201. The light emitting component 202 may fixed by using an epoxy resin or the like which may contain silver (Ag), for example. In some embodiments, an n electrode and a p electrode of the light emitting component 202 may be further connected to metal terminals 205 and installed on the casing 204 by means of conductive wires 203. Similar to the lead type LED 100, the chip type light emitting diode 200, may produce a fluorescent light via the phosphor and LED light. The produced light may be transmitted such that only a portion of the light emitting component of the LED is absorbed by the phosphor. The unabsorbed spectrum produced may be mixed with the fluorescence output by the phosphor, so that the light emitting diode 200 outputs a light having a spectrum different from that of the LED light emitted by the light emitting component 202.

Embodiments of the light emitting device, such as a light emitting diode, may contain the phosphor as described above, and additionally may have one or more of the following features:

In some embodiments, the light emitted by a light emitting component, may be emitted through an electrode which supplies electric power to the light emitting component. Emitted light may be partly blocked by the electrode formed on the light emitting component resulting in a particular emission pattern. This may result in the light not being emitted uniformly in every direction. The light emitting diode device described herein may further contain a fluorescent phosphor material, which may emit light uniformly over a wide wavelength range without forming undesirable emission patterns because the fluorescent phosphor material may diffuse light being emitted by the light emitting component. Although light emitted by the light emitting component may have a monochromatic peak, the peak may be broad and have a high color rendering property. This characteristic may be advantageous for an application which desires wavelengths of a relatively wide range.

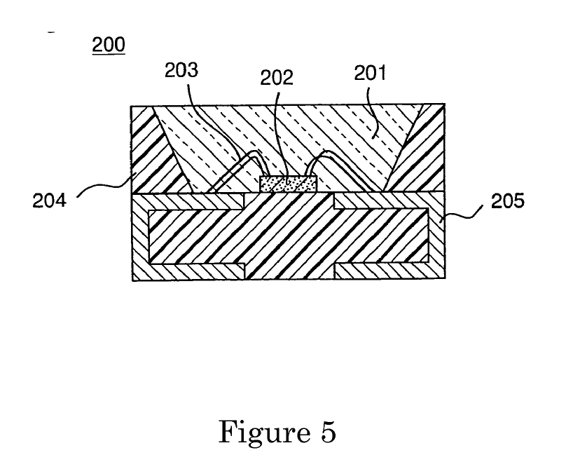

Some of the embodiments of light emitting devices described below may have the configurations shown in FIG. 4 or FIG. 5. The light emitting device may include a light emitting component which uses a semiconductor with a nitride compound containing an active layer, having relatively high energy in the visible region of the light spectrum. A particular phosphor may be combined with the light emitting component, to produce favorable properties to the emitted light, including high luminance, reduced degradation, increased emission efficiency and less color shift over an extended period of use.

In general, the phosphor may be any fluorescent material which absorbs light of a shorter wavelength and emits light of a longer wavelength than the absorbed light. The phosphor may also have a higher efficiency than a fluorescent material which absorbs light of a long wavelength and emits light of a short wavelength. It is therefore preferable to use a nitride based semiconductor as the light emitting component because it is capable of emitting blue or ultraviolet light having short wavelengths. Such nitride based active layers of the semi-conductor may include gallium nitride, indium nitride, aluminum nitride, gallium indium nitride, aluminum indium nitride and a combination thereof. In the exemplary embodiments, it is preferable that the light emitting component has a high luminance.

A phosphor which may be used in combination with the nitride compound semiconductor light emitting component may have the following properties:

Excellent resistance against light to endure light of a high intensity for a long period of time, because the fluorescent material may be installed in the vicinity of the light emitting components 102, 202 and may be exposed to light of intensity as high as about 30 to 40 times that of sun light.

In some embodiment, the light emitting components 102, 202 may be capable of efficiently emitting light in the blue region of the emission spectrum of visible light or emitting ultraviolet light, allowing for the excitation of the phosphor by means of the light emitting components 102, 202. In an embodiment wherein the mixing of colors is used, the phosphor should be capable of absorbing a portion of the blue or ultraviolet light emission spectrum with a high efficiency.

Embodiments of the phosphor may also have the capability to emit light from green to red regions of the visible light emission spectrum, for the purpose of mixing with blue light emitted from light emitting components, in order to generate white light. It may also be desirable for the phosphor to produce light having a good temperature characteristics suitable for the location in the vicinity of the light emitting components 102, 202 and the resultant influence of temperature difference due to heat generated by the chip when lighting, as well as possessing the capability to continuously change the color tone in terms of the proportion of composition or ratio of mixing a plurality of fluorescent phosphor materials.

In some embodiments, the light emitting device, such as an LED, may employ an aluminum nitride, gallium nitride, indium nitride, gallium indium nitride or aluminum gallium nitride compounds into the active layer of a semiconductor, acting as a light emitting component. The formula for the active layers of the semi-conductor may be represented by the general formula Ga₁₋ₓInₓN and/or Al₁₋ₓGaₓN. The semi-conductor having an aluminum nitride, gallium nitride or indium nitride active layer may have a high-energy band gap in the light emitting layer that may be capable of emitting blue or ultraviolet light. The light emitting component, such as the semi-conductor may utilize a phosphor activated by an activator/dopant to shift the blue or ultraviolet light into a more desirable color, such as white. In some embodiments, the phosphor may be able to activate the phosphor's absorption of a portion of the emission spectrum emitted by the light emitting component.

A phosphor having the general formula Ca₁₊ₓSr₁₋ₓGa_{y}In_{2-y}S_{z}Se_{3-z}F₂, wherein 0≦x≦1, 0≦y≦2 and 0≦z≦3 may be used in some embodiments. Various embodiments of the phosphor may include Ca₂Ga₂S₃F₂, CaSrGa₂SSe₂F₂, CaSrGaInSe₃F₂, CaSrGa₂S₃F₂, or Ca₂Ga₂SSe₂F₂. Furthermore, embodiments of the activator/dopant used to activate the phosphor may include the elements of europium (Eu), cerium (Ce), praseodymium (Pr), terbium (Tb), ruthenium (Ru), erbium (Er), manganese (Mn), ionic forms thereof and mixtures thereof.

An example embodiment of a light emitting component may be constructed out of a semi-conductor having a gallium nitride active layer and a phosphor described above, doped with Eu²⁺. With this configuration, the light emitting device may emit white light by blending the blue light emitted by the light emitting components 102, 202 and yellow, green or red light emitted by the phosphor excited by the blue light. Because the Ca₁₊ₓSr₁₋ₓGa_{y}In_{2-y}S_{z}Se_{3-z}F₂ phosphor activated with Eu²⁺ or any of the other activators described above which may be used in the light emitting device, have a light resistance and weatherability, the phosphors can emit light with extremely small degrees of color shift and decrease the luminance of emitted light even when irradiated by very intense light emitted by the light emitting components 102, 202, over a long period of time.

The phosphor used with the light emitting device which, when excited by visible light or ultraviolet rays emitted by a light emitting component, such as a semiconductor light emitting active layer may emit light of a wavelength different from that of the excitation light emitted from the light emitting component. The phosphor may be a material having the general formula Ca₁₊ₓSr₁₋ₓGa_{y}In_{2-y}S_{z}Se_{3-z}F₂ (0≦x≦1, 0≦y≦2, 0≦z≦3, particularly 0<x<1, 0<y<2, 0<z<3) and may be activated with an activator or dopant, including the elements of the periodic table Eu, Ce, Pr, Tb, Ru, Er, Mn, ionic forms thereof and mixtures thereof. According to the present disclosure, examples of activated phosphors may include Ca₂Ga₂S₃F₂:Er, CaSrGa₂SSe₂F₂:Ce, CaSrGaInSe₃F₂:Mn, CaSrGa₂S₃F₂:Ru, or Ca₂Ga₂SSe₂F₂:Tb. The blue or ultraviolet light emitted by the light emitting component employing the gallium nitride, indium nitride, aluminum nitride, gallium aluminum nitride or aluminum indium nitride active layer of the semiconductor and the yellowish light emitted by the phosphor are in the relation of complementary colors. The combining of the colors allows for a white color to be output by blending the light emitting component's light and the light emitted from the activated phosphor.

In some embodiments, the phosphor may be used by blending the phosphor with a resin which forms the coating resin 101 or the coating material 201 (detailed later). The color tone of the light emitting device may be adjusted to various colors, including white or an incandescent lamp color by controlling the mixing proportion of the resin or the quantity used in filling the cup 105a or the recess of the casing 204 in accordance to the wavelength of light emitted by the active layer of the light emitting component.

Distribution of the phosphor concentration, for example, in the range of 0.001 to 10 mole percent, may have influence on the color blending and durability of the light emitting device. When the concentration of phosphor increases from the surface of the coating or molding where the phosphor is contained toward the light emitting component, it becomes less likely to be affected by extraneous moisture thereby making it easier to suppress any deterioration due to moisture. On the other hand, when the concentration of phosphor increases from the light emitting component toward the surface of the molding, it becomes more likely to be affected by extraneous moisture, but less likely to be affected by the heat and radiation from the light emitting component, thus making it possible to suppress the deterioration of the phosphor. Such distributions of the phosphor concentration can be achieved by selecting or controlling the material containing the phosphor, the forming temperature and viscosity, and the configuration and particle size distribution of the phosphor.

By using the phosphors described above, a light emitting device with excellent emission characteristics can be constructed. The fluorescent material of the activated phosphor may have enough light resistance for high-efficient operation even when arranged adjacent to or in the vicinity of the light emitting components 102, 202 with radiation intensity within the range from 3 Wcm⁻² to 10 Wcm⁻².

The activated phosphors of the embodiments described herein, may be resistant to heat, light and moisture, and are therefore capable of absorbing excitation light having a peak at a wavelength near 450 nm as shown in FIGS. 2a-2d. The activated phosphors may also emit a light of broad emission spectrum having a peak wavelength between approximately 490-650 nm. The broad emission spectrum may have a peak wavelength around 550, 560, 570 or 580 nm. In some embodiments, the tail portion of the broad emission spectrum may extend to greater than 650 nm, 680 nm, 700 nm or 750 nm or beyond. Each of the phosphors having the general formula Ca₁₊ₓSr₁₋ₓGa_{y}In_{2-y}S_{z}Se_{3-z}F₂ (0≦x≦1, 0≦y≦2, 0≦z≦3, particularly 0<x<1, 0<y<2, 0<z<3) may be formed using the methods described above and exemplified in examples 1-5 of this disclosure.

The phosphors represented by the general formula Ca₁₊ₓSr₁₋ₓGa_{y}In_{2-y}S_{z}Se_{3-z}F₂ may emit light of wavelengths 400 nm and longer with higher efficiency upon excitation. The absorption and emission spectrum of the phosphor may be adjusted based on the composition of the phosphors being used. For example, in FIG. 2a, a comparison between light emission from Eu²⁺ doped CaSrGa₂SSe₂F₂ and Eu²⁺ doped Ca₂Ga₂SSe₂F₂ is depicted. Looking at the comparative photoluminescence (PL) spectra, it can be seen that the CaSrGa₂SSe₂F₂ emits a higher intensity peak of emitted light between 500-600 nm wavelengths. On the other hand, the Ca₂Ga₂SSe₂F₂ exhibits a higher intensity of emission at longer wavelengths, particularly exemplified by the peak exhibited between 550-700 nm. This exemplifies that different phosphors being used alongside different activator or dopants may be substituted depending on the light emitting component of the light emitting device and the desired outcome of the emitted spectrum desired from the light emitting device.

In some embodiments of the light emitting device of the present disclosure, a mixture of two or more different kinds of phosphors having the general formula Ca₁₊ₓSr₁₋ₓGa_{y}In_{2-y}S_{z}Se_{3-z}F₂ (0≦x≦1, 0≦y≦2, 0≦z≦3, particularly 0<x<1, 0<y<2, 0<z<3) may be used, including alloys of the phosphor having different amounts of Ca, Sr, Ga, In, S, Se and F₂.

In some embodiments of the light emitting device, a light emitting component may be embedded in a molding material as shown in FIG. 4 and FIG. 5. The light emitting component 102, 202 used in the light emitting device, capable of efficiently exciting the phosphor materials activated with an activator, may be constructed by forming a light emitting active layer of a semiconductor such as gallium nitride, gallium indium nitride, indium nitride, aluminum nitride or aluminum gallium nitride, on a substrate using the metalorganic chemical vapor deposition (MOCVD) process. In some embodiments, the structure of the light emitting component may be homostructure, heterostructure or double-heterostructure which may have MIS junction, PIN junction or PN junction.

Various wavelengths of emission by the light emitting component can be selected depending on the material of the semiconductor layer and the crystallinity thereof. In some embodiments, the light emitting component may be made in a single quantum well structure, whereas in other embodiments, a multiple quantum well structure may be used where a semiconductor activation layer is formed extremely thin so that a quantum effect can occur. According to one exemplary embodiment, a light emitting diode capable of emitting with higher luminance without deterioration of the phosphor can be made by making the activation layer of the light emitting component in single quantum well structure of aluminum nitride, aluminum gallium nitride, gallium nitride, gallium indium nitride and a combination of material thereof.

In an embodiment where the semiconductor material is gallium nitride or gallium indium nitride, sapphire, spinnel, SiC, Si, ZnO or the like may be used as the semiconductor substrate. The use of sapphire as a substrate may allow for the formation of gallium nitride with good crystallinity. A gallium nitride semiconductor layer may be formed on the sapphire substrate to form a PN junction via a buffer layer of GaN, GaIN, AlN, AlGaN, etc. Embodiments of the gallium nitride semiconductor may have N type conductivity under conditions where it has not been doped with any impurity. However, in alternative embodiments, an N type gallium nitride semiconductor having desired properties (carrier concentration, etc.) such as improved light emission efficiency, may be desired. In such an embodiment, the active layer of the semiconductor material may be doped with an N type dopant such as Si, Ge, Se, Te, and C, ionic forms thereof and mixtures thereof.

In order to form a P type active layer, such as in a gallium nitride semiconductor material, an embodiment may be doped with a P type dopant such as Zn, Mg, Be, Ca, Sr, Ba, ionic forms thereof and mixtures thereof. In some embodiments, it may be difficult to turn the active layer of the semiconductor material to P type simply by doping with a P type dopant. Therefore, in some embodiments, it may be preferable to treat the active layer of the semiconductor material doped with P type dopant using a process of heating in a furnace, irradiation with an electron beam and plasma irradiation, in order to turn it into a P type. After exposing the surfaces of P type and N type of the active layer semiconductors, etching or other process may be performed in order to produce electrodes of the desired shapes on the semiconductor layers by sputtering or vapor deposition.

Furthermore, the semiconductor wafer which has been formed, may be further cut into pieces by means of a dicing saw, or separated by an external force after cutting grooves (half-cut) which may have a width greater than the blade edge width. In other embodiments, the semiconductor wafer may be cut into chips by scribing a grid pattern of extremely fine lines on the semiconductor wafer by means of a scriber having a diamond stylus using straight reciprocal movement.

In order to emit white light with the light emitting device, embodiments of the device may emit from the light emitting component, an emission spectrum having a wavelength of light between approximately 380 nm to 530 nm (inclusively) taking into consideration the complementary color relationship with the phosphor and deterioration of resin. In some cases embodiments may emit a wavelength between 420 nm to 490 nm inclusive. In additional embodiments, the wavelength emitted may be between 450 nm to 475 nm. The emission spectrum of the white light emitting device is shown in FIGS. 2a to 2d. In FIGS. 2a-2d, an emission having a peak around 450 nm is exhibited. This peak represents the light emitted by the light emitting component, while the emission having a peak around 500-700 nm depending on the phosphor used, is the photo luminescent emission excited by the light emitting component.

In some embodiments of the light emitting device, the phosphor and activator, forming the activated phosphor may produce a broad emission spectrum, absorbing a portion of the light emitted by the light emitting component, producing the broad emission which may be seen as visible white light. In such an embodiment, the light emitting component may produce from its emission spectrum, light that is unabsorbed by the activated phosphor. The combination of the broad emission spectrum produced by the activated phosphor and the unabsorbed light's emission spectrum may overlap each other and form a continuous combined spectrum, which may also produce light having a white color.

In some embodiments, a light emitting component which does not excite the phosphor or activated phosphor material may be used together with the light emitting component which emits light that excites the phosphor or activated phosphor material. Specifically, in addition to the phosphor material and the active layer of the semiconductor capable of exciting the phosphor, the light emitting component may further include a light emitting layer made of gallium phosphide, gallium aluminum arsenide, gallium arsenic phosphide, indium aluminum phosphide, or a combination thereof, may be arranged together. With this configuration, light emitted by the light emitting component which does not excite the phosphor material may be radiated externally without being absorbed by the phosphor material. This may result in the formation of a light emitting device which can emit the entire spectrum of colors including red, orange, yellow or green light in addition to the white light.

Embodiments of methods for emitting white colored light from the light emitting device may include the steps of providing a light emitting device that has a light emitting component such as a semi-conductor with an active layer (described above) and emitting from the light emitting component, a blue or ultraviolet light. Furthermore, steps for producing the white colored light may further comprise the steps of providing a phosphor having the general formula Ca₁₊ₓSr₁₋ₓGa_{y}In_{2-y}S_{z}Se_{3-z}F₂, wherein 0≦x≦1, 0≦y≦2 and 0≦z≦3 and activating the phosphor with an activator/dopant such as those previously described, including the elements of europium (Eu), cerium (Ce), praseodymium (Pr), terbium (Tb), ruthenium (Ru), erbium (Er), manganese (Mn), ionic forms thereof and mixtures thereof. The activated phosphor may proceed in absorbing a part or portion of the blue or ultraviolet light emitted from the light emitting component. Subsequently the activated phosphor may proceed by emitting from the activated phosphor, a spectrum of light that visibly appears white in color. In some embodiments of the method, step of emitting blue or ultraviolet light may produce an emission spectrum having a wavelength between 380-500 nm. Moreover, the step of emitting white light from the activated phosphor may produce a broad emission spectrum having a peak wavelength between 490-650 nm and a tail emission wavelength extending beyond 650 nm, beyond 700 nm and/or beyond 750 nm. In some embodiments of the method for producing a white colored light from the light emitting device, the unabsorbed light passing through the activated phosphor from the light emitting component may overlap with the broad emission spectrum produced by the activated phosphor to form a continuous combined spectrum.

In some embodiments of the light emitting device, conductive wires may be used for making connection with the electrodes of the light emitting components 102, 202. The exemplary conductive wires 103, 203 should have good electric conductivity, good thermal conductivity and good mechanical connection with the electrodes of the light emitting components 102, 202. For example, in some embodiments, thermal conductivity may be 0.01 cal/(s) (cm²) (° C./cm) or higher, and in alternative embodiments 0.5 cal/(s) (cm²) (° C./cm) or higher.

For workability, the diameter of the conductive wire may be between 10 μm to 45 μm inclusively. Embodiments of the conductive wire may be a metal such as gold, copper, platinum or aluminum or an alloy thereof. When a conductive wire of such material and configuration is used, it can be easily connected to the electrodes of the light emitting components, the inner lead and the mount lead by means of a wire bonding device.

Embodiments of the mount lead 105 may comprise a cup 105a and a lead 105b. The mount lead 105 may be constructed to have a sufficient size large enough for mounting the light emitting component 102 with the wire bonding device in the cup 105a. In some embodiments, a plurality of light emitting components may be installed in the cup. In such an embodiment, the mount lead may also be used as a common electrode for the light emitting component. When the light emitting component is installed in the cup of the mount lead and the cup is filled with the phosphor material, light emitted by the phosphor material may, even if isotropic, be reflected by the cup in a desired direction and therefore erroneous illumination due to light from other light emitting device mounted nearby can be prevented. An erroneous illumination may refers to such a phenomenon wherein other light emitting devices mounted nearby appear as though they are lighting the light emitting device, despite not being supplied with power.

Bonding of the light emitting component 102 and the mount lead 105 with the cup 105a may be achieved by means of a thermoplastic resin such as epoxy resin, acrylic resin or imide resin. When a face-down light emitting component (such as a type of light emitting component wherein the emitted light is extracted from the substrate side and is configured for mounting the electrodes to oppose the cup 105a) is used, a silver paste, carbon paste, metallic bump or the like, may be used for bonding and electrically connecting the light emitting component and the mount lead. In some embodiments, the light emitting component and the mount lead may be connected at the same time.

Further, in order to improve the efficiency of light utilization of the light emitting device in some embodiments, the surface of the cup of the mount lead wherein the light emitting component is mounted may be mirror-polished to give reflecting function to the surface. In such an embodiment, the surface roughness may have a surface roughness maximum (Rₘₐₓ) between 0.1 to 0.8 microns inclusively. Moreover, embodiments may have a mount lead with an electrical resistivity less than or equal to 300 μΩ·cm and in some embodiments, less than or equal to 3 μΩ·cm, at 25° C.

In embodiments wherein there is a mounting of a plurality of light emitting components on the mount lead, the light emitting components may generate significant amount of heat and therefore high thermal conductivity may be needed. Specifically, the thermal conductivity of the light emitting components may be approximately 0.01 cal/(s) (cm²) (° C./cm) or higher, and in some embodiment, 0.5 cal/(s) (cm²) (° C./cm) or higher. Materials which may satisfy these requirements may contain steel, copper, copper-clad steel, copper-clad tin and metallized ceramics.

Embodiments of the inner lead 106 may be connected to one of electrodes of the light emitting component 102 mounted on the mount lead 105 by means of conductive wire or the like. In embodiments of the light emitting device where a plurality of the light emitting components are installed on the mount lead, a plurality of inner leads 106 may be arranged in such a manner that the conductive wires do not touch each other. For example, contact of the conductive wires with each other may be prevented by increasing the area of the end face where the inner lead is wire-bonded. Surface roughness of the inner lead end face connecting with the conductive wire may be preferably from 1.6 microns to 10 microns inclusive. In some embodiments, the inner lead may be formed into a desired shape, by punching with a die. Further, in other embodiments, it may be made by punching to form the inner lead then pressurizing it on the end face thereby controlling the area and height of the end face.

Embodiments having an inner lead should have good connectivity with the bonding wires, which are conductive wires, and have good electrical conductivity. Specifically, the electrical resistivity may be less than or equal to 300 μΩ·cm and in some embodiments less than or equal to 3 μΩ·cm. Materials which may satisfy these requirements may contain iron, copper, iron-containing copper, tin-containing copper, copper-plated aluminum, gold-plated aluminum or silver-plated aluminum, iron and copper.

The coating material 101 may be provided in the cup of the mount lead apart from the molding material 104, and may contain the phosphor which converts the light emitted by the light emitting component. The coating material 101 may be a transparent material having good weatherability such as an epoxy resin, urea resin, silicone or glass. In some embodiments, a dispersant may be used together with the phosphor. Examples of the dispersant may include barium titanate, titanium oxide, aluminum oxide, silicon dioxide and the like. In some embodiments wherein the phosphor material is formed by sputtering, such as by physical vapor deposition, the coating material may be omitted. In such an embodiment, a light emitting device may be capable of bending colors by controlling the film thickness or providing an aperture in the phosphor material layer.

The molding 104 may have the function of protecting the light emitting component 102, the conductive wire 103 and the coating material 101 (which contains the phosphor) from external disturbance or damage. In some embodiments, the molding material 104 may contain a dispersant, The dispersant may be a substance or agent such as a non-surface active polymer which may improve the dispersion of particles of the molding in order to prevent the occurrence of settling. For example, dispersants may include polyacrylic acid, polyacrylamide, polyethylene glycol, zinc sulfonate 2-butoxyethanol, and polycarboxylates. In some embodiments, the molding material 104 may be made in a configuration of convex lens or concave lens. Moreover, embodiments of the molding 104 may have an elliptical shape. Embodiments of the molding material 104 may be formed in a structure using multiple layers of different materials being laminated. Transparent materials having high weatherability may be used as the molding material. These materials may include epoxy resin, urea resin, silicon resin, glass of a combination of materials thereof. As the dispersant, barium titanate, titanium oxide, aluminum oxide, silicon dioxide and the like may be used.

In addition to the dispersant, some embodiments of the molding material may further contain the phosphor therein. The phosphor may be contained either in the molding material or in the coating material. When the phosphor is contained in the molding material, the angle of view can be further increased. In alternative embodiments, the phosphor may be contained in both the coating material and the molding material. Furthermore, embodiments may also include a resin containing the phosphor as the coating material while using glass, different from the coating material, as the molding material. This makes it possible to manufacture a light emitting device which is less subject to the influence of moisture while having good productivity. In some embodiments, the molding and the coating may be constructed out of the same material. This may be beneficial as it allows the molding and coating to match the refractive indexes.

In some embodiments, adding the dispersant and/or a coloration agent such as titanium dioxide, ferric oxide, polyesters, or natural dyes derived from plants leaves and flowers, to the molding material may have an effect of masking the color of the phosphor material as well as further improving the color mixing performance. That is, the phosphor material may absorb the ultraviolet or blue light emission spectrum emitted from the light emitting component and emit a light giving such an appearance as though it was colored yellow. In certain embodiments, the dispersant, such as polyacrylamide, contained in the molding material may turn the molding material a milky white color allowing for the coloration agent render the desired color to the molding. Thus the color of the phosphor material may not be able to be recognized or observed by the user.

In an alternative embodiment, the light emitting device, such as a light emitting diode, may be configured using a phosphor material including two or more kinds of phosphors of different compositions. With this configuration, a light emitting device may emit a desired color tone by controlling the concentrations of the two or more phosphor materials present to manipulate the color being output when the color of light emitted from each phosphor mixes or combines. The control of the emitted color can be made even when the wavelength of the light emitted by the light emitting component deviates from the desired value due to variations in the production process. In this case, the emission color of the light produced by the emitting device can be made constant using a phosphor material having a relatively short emission wavelength for a light emitting component of a relatively short emission wavelength. Conversely, if the light emitted from the light emitting component has a long wavelength, a phosphor material having a relatively long emission wavelength may be used.

Phosphor used in the light emitting component of the alternative embodiment having two or more phosphors present may include as a second phosphor, those phosphors and activators described above, except that two or more kinds of phosphors may have different compositions. However, although the phosphors have different compositions, the same activator/dopant may be present for both phosphors, or a different activator/dopant may be used for each phosphor.

The light emitting device of the alternative embodiment having two or more phosphors present, may be provided with high weatherability in some embodiments by controlling the distribution of the phosphor (such as by tapering the concentration with the distance from the light emitting component). Such a distribution of the phosphor concentration can be achieved by selecting or controlling the material which contains the phosphor, controlling the forming temperature and viscosity, and the configuration and particle size distribution of the phosphor. Thus, in the alternative embodiment described, distribution of the phosphor material concentration may be determined according to the operating conditions. Also, according to the alternative embodiment, efficiency of light emission may be increased by designing the arrangement of the two or more kinds of phosphor materials (for example, arranging in the order of nearness to the light emitting component) according to the light generated by the light emitting component.

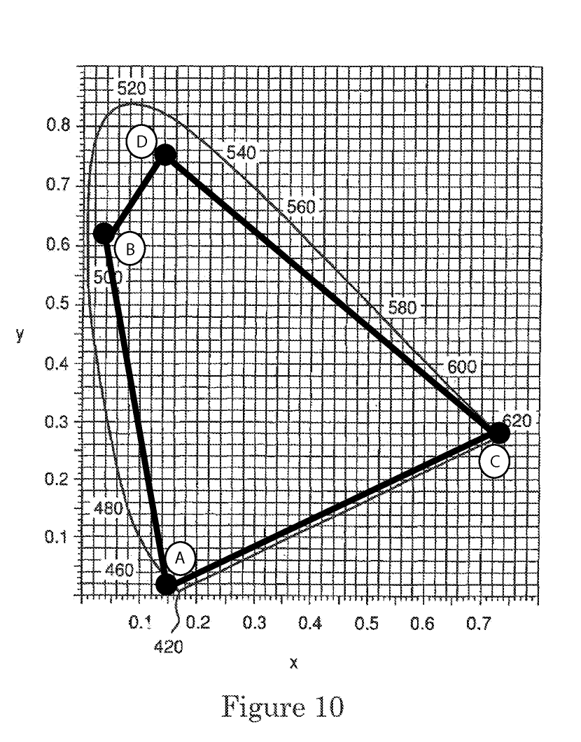

The light emitting device of the alternative embodiment having two or more phosphors may be made by using two or more kinds of phosphors having the general formula Ca₁₊ₓSr₁₋ₓGa_{y}In_{2-y}S_{z}Se_{3-z}F₂, wherein 0≦x≦1, 0≦y≦2 and 0≦z≦3. Each of the two or more phosphor materials may have a different composition as described above. This makes it possible to make a light emitting device capable of emitting light of desired color efficiently. That is, when a wavelength of light emitted by the semiconductor's light emitting component corresponds to a specific chromaticity, light of any color in the shaded region enclosed by points A, B, C and D in FIG. 10 which is the chromaticity points (points C and D) of the two or more kinds of phosphor materials of different compositions can be emitted. Accordingly, in alternative embodiments, color can be controlled by changing the compositions or quantities of the light emitting devices components and phosphor materials. For example, the current sent to through the semiconductor may be increased resulting in an increase flux to the active layer, thus increase the blue light emitted, resulting in a cooler white light being observe. In another example, a phosphor absorbing a certain spectra of light from the light emitting component may be removed and replaced with another phosphor which may absorb a different wavelength of light. Accordingly, the output from the two separate phosphors will have a different appearance.

In particular, a light emitting device having less variation in the emission wavelength can be made by selecting the phosphor materials according to the emission wavelength of the light emitting component, thereby compensating for the variation of the emission wavelength of the light emitting component. Also a light emitting device including RGB components with high luminance may be made by selecting the emission wavelength of the phosphor materials.

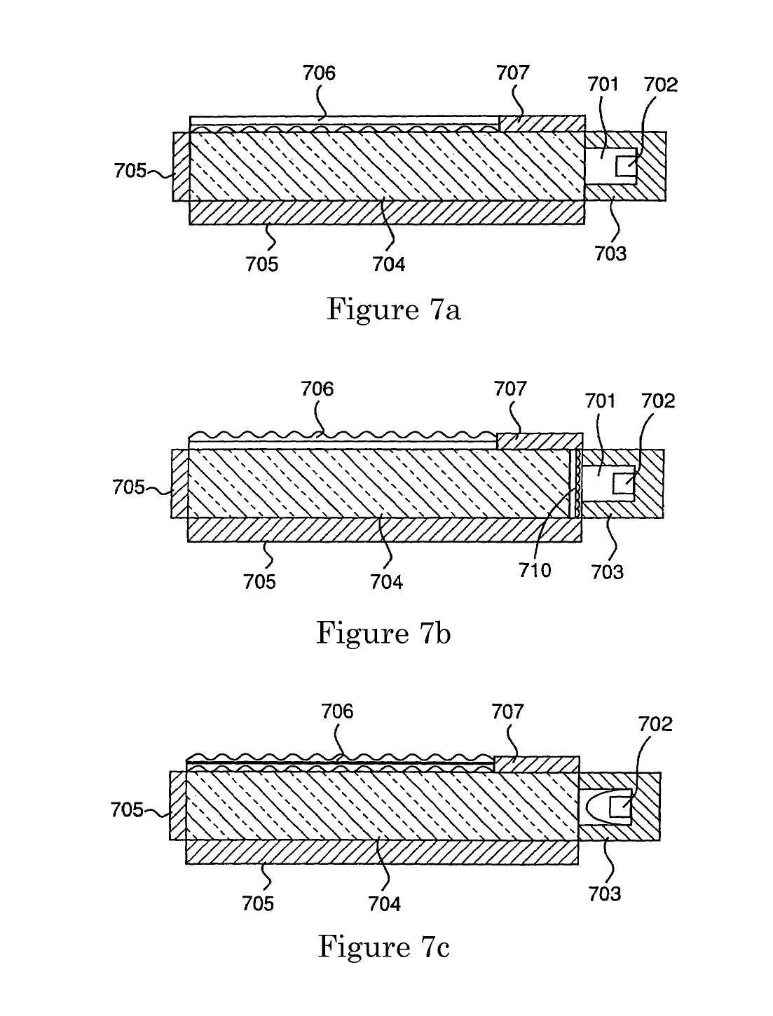

In another embodiment, the light emitting component may be a planar light source as shown in FIGS. 7a-7c, rather than a light emitting diode depicted in FIGS. 4 and 5. In the embodiments using a planar light source, the phosphor and activator described above may be contained in a coating material 701. With this embodiment's configuration, the ultraviolet and/or blue light emitted by the active layer of the semiconductor may be color-converted and output in a planar state via an optical guide plate 704 and a dispersive sheet 706.

Specifically, a light emitting component 702 of the planar light source of FIG. 7a may be secured in a metal substrate 703 having an inverse C shape whereon an insulation layer and a conductive pattern (not shown) may be formed. An electrode may be electrically connected to the light emitting component and conductive pattern. After electrically connecting the electrode, the phosphor may be mixed with epoxy resin and applied into the inverse C-shaped metal substrate 703 whereon the light emitting component 702 is mounted. The light emitting component may be secured onto an end face of an acrylic optical guide plate 704 by means of an epoxy resin. In some embodiments, a reflector film 707 containing a white diffusion agent may be arranged on one of principal planes of the optical guide plate 704 where the dispersive sheet 706 is not formed, for the purpose of preventing fluorescence.

Similarly, a reflector 705 may be provided on the entire back surface of the optical guide plate 704 and on one end face where the light emitting component is not provided. This embodiment may be used to improve the light emission efficiency. With this configuration, light emitting diodes for planar light emission which generate enough luminance for the back light of a liquid crystal display (LCD) can be made. Application of the light emitting device using planar light emission to a liquid crystal display can be achieved by arranging a polarizer plate on one principal plane of the optical guide plate 704 via liquid crystal injected between glass substrates (not shown) whereon a translucent conductive pattern is formed.

Referring to the embodiments of the light emitting devices of FIGS. 7b and 7c, the light emitting device shown in FIG. 7b may be made in such a configuration that blue or ultraviolet light emitted by the light emitting diode 702 may be converted to white light by a color converter 710 which contains one or more phosphors and is output in a planar state via an optical guide plate 704. Similarly, the light emitting device shown in FIG. 7c may be made in such a configuration that blue or ultraviolet light emitted by the light emitting component 702 may be turned to planar state by the optical guide plate 704, then converted to white light by a dispersive sheet 706 which contains one or more phosphors formed on one of the principal planes of the optical guide plate 704. This may result in the output white light in the planar state. In some embodiments, the phosphor may be contained in the dispersive sheet 706 or in alternative embodiments, the phosphor may be formed in a sheet by spreading it together with a binder resin over the dispersive sheet 706. The binder, including the phosphor, may be formed in dots, not sheet, directly on the optical guide plate 704 in some alternative embodiments.

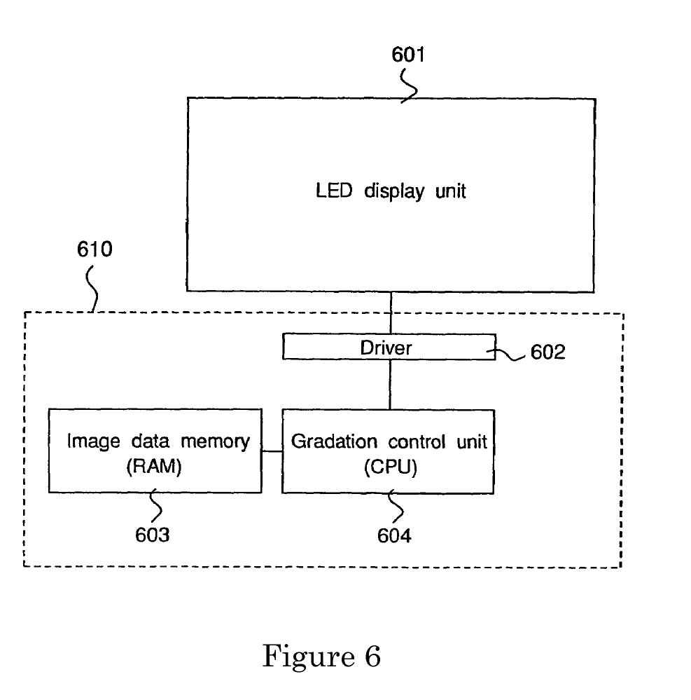

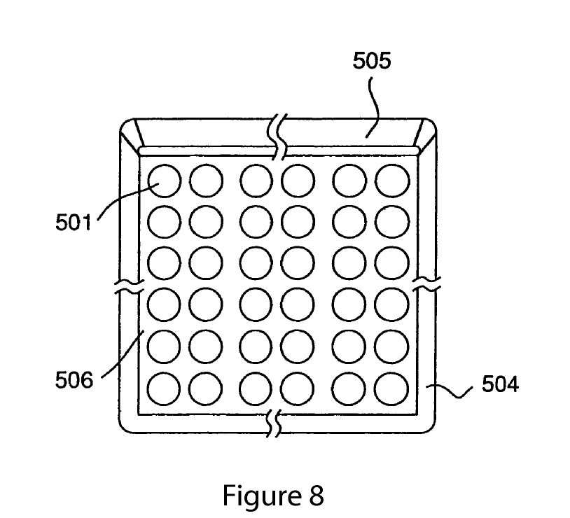

Each of the light emitting devices described above may be applied in conjunction with a display device. FIG. 6 outlines a block diagram showing the configuration of the display device according to the present invention. As shown in FIG. 6, the display device comprises an LED display unit 601 and a drive circuit 610 having a driver 602, video data storage means 603 and tone control means 604 which may be controlled by the CPU. The LED display unit 601, in some embodiments may have white light emitting devices 501 such as those described above or depicted in FIG. 4 or FIG. 5. Each of the white light emitting devices 501 may be arranged in a matrix configuration, and they may be contained in a casing 504 such as the one shown in FIG. 8. This casing 504 may be used as monochromatic LED display device in some embodiments. Embodiment of the casing 504 may be may further include a light blocking material 505 being formed integrally therewith.

The drive circuit 610 may be equipped with video data storage means such as RAM, SRAM, DRAM, SDRAM, DDR SDRAM, or RDRAM 603 for temporarily storing display data which is input, the tone control means 604 which computes and outputs tone signals for controlling the individual light emitting devices of the display device 601 to light with the specified brightness according to the data read from RAM 603, and the driver 602 which is switched by signals supplied from the tone control means 604 to drive the light emitting device to light.

In some embodiments, the tone control circuit 604 retrieves data from the RAM 603. The tone control circuit 604 may compute the duration of lighting provided by the light emitting devices of the display device 601. Subsequently, the tone control circuit 604 may then output pulse signals for turning on and off the light emitting devices such as LEDs to the display device 601. In the display device constituted as described above, the display device 601 may be capable of displaying images according to the pulse signals which are input from the drive circuit.

In some embodiments, the display device 601 may displays white light by using light emitting devices emitting three colors, red, green and blue (RGB). The combination of RGB may be displayed while controlling the light emission output of the R, G and B light emitting devices and accordingly control the light emitting devices by taking the emission intensity, temperature characteristics and other factors of the light emitting devices into account. This combination of RGB and the lighting characteristics may result in a complicated configuration of the drive circuit which drives the display device. In a display device that uses a light emitting device having activated phosphors, such as those embodiments described throughout this application, which can emit white light without utilizing RGB diodes, it is not necessary for the drive circuit of the described embodiments to individually control the R, G and B light emitting devices. Overall, this makes it possible to simplify the configuration of the drive circuit and make the display device at a low cost.

A display device which displays white light by using light emitting diodes of three kinds, RGB, the three light emitting diodes must be illuminated at the same time and the light from the light emitting diodes must be mixed in order to display white light by combining the three RGB light emitting diodes for each pixel, resulting in a large display area for each pixel and making it difficult to display with high definition. Embodiments of the display device described in this disclosure in contrast, can display white light using a single light emitting diode, and are therefore capable of displaying white light having higher definition. Further, with the display devices which display images by mixing the colors of three light emitting diodes, display color changes may occur due to blocking of some of the RGB light emitting diodes depending on the viewing angle. Embodiments of the LED display devices according to this disclosure do not have such a problem.

As described above, the embodiments of the display device, which is capable of emitting white light, is capable of displaying stable white light with higher definition and has an advantage of less color unevenness. The display device embodiments described may be capable of displaying white light in a manner that may impose less stimulation to the eye making the embodiments better suited for use over a long period of time as opposed to the conventional LED display devices which employs only red and green colors which may cause more stimulation and fatigue to the eyes of the user.

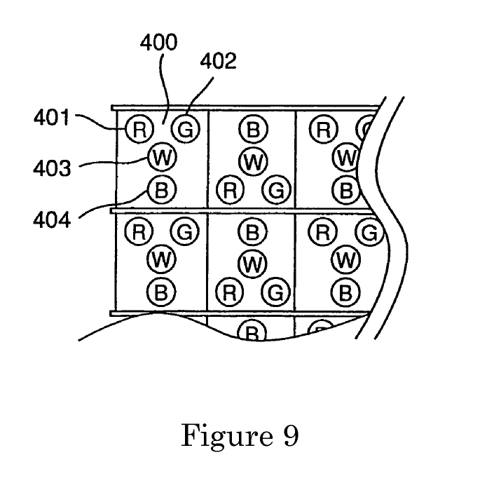

In some embodiments, the light emitting device of the present disclosure may be used to constitute an LED display device wherein one pixel 400 includes three RGB light emitting devices 401, 402, 404, and one embodiment of the light emitting device 403 described throughout this disclosure, as shown in FIG. 9. By connecting the display device and a drive circuit, an embodiment of the display device capable of displaying various images can be created. The drive circuit of this display device may, similarly to the case of monochrome display device, video data storage means for temporarily storing the input display data, a tone control circuit which processes the data stored in the video data storage to compute tone signals for lighting the light emitting devices with specified brightness and a driver which may switched by the output signal of the tone control circuit to cause the light emitting devices to illuminate. The drive circuit may act exclusively for each of the RGB light emitting devices and the white light emitting device. The tone control circuit may compute the duration of lighting the light emitting from the light emitting device from the data stored in the RAM, and may output pulse signals for turning on and off the light emitting devices. When displaying white light, the width of the pulse signals for lighting the RGB light emitting devices may be made shorter, or peak value of the pulse signal may be lower, or no pulse signal may be provided. On the other hand, a pulse signal may be provided to the white light emitting device in compensation thereof. This may cause the display device to display white light.

As described above, the brightness of the display can be improved by adding the white light emitting device to the RGB light emitting devices. When RGB light emitting devices are combined to display white light, one or two of the RGB colors may be enhanced or overpower the others, resulting in a failure to display pure white depending on the viewing angle. Such a problem may be solved by adding the white light emitting device to the display device to even out the uneven emissions by the RGB devices.

In some embodiments of the drive circuit, such as in a display device described above, a CPU may be provided separately as a tone control circuit. The separate CPU may compute the pulse signal for lighting the white light emitting device, such as a LED, with a specified brightness. The pulse signal which is output from the tone control circuit may be given to the white light emitting device driver. The white light emitting device may illuminate when the driver is turned on, and goes out when the driver is turned off.

In some embodiments, the light emitting device may be present in a traffic signal which may be considered a kind of display device. Embodiments of the light emitting device may allow for such advantages as stable illumination over a long period of time and decrease or elimination of color unevenness, even when part of the light emitting device becomes non-operational (goes out). Embodiments of a traffic signal employing embodiments of the light emitting device may have such a configuration such that the white light emitting devices (or LEDs) are arranged on a substrate whereon a conductive pattern is formed. A circuit of light emitting devices may be connected in series or parallel. Additionally, two or more sets of the light emitting devices may be used, each having the light emitting devices arranged in spiral configuration. When all light emitting devices are arranged, they cover the entire area of the substrate in a circular configuration.

After connecting power lines by soldering for the connection of the light emitting devices and the substrate with external power supply, the display device may be further placed in an aluminum die cast chassis equipped with a light blocking member and may be sealed on the surface with silicone rubber filler. The chassis may be provided with a white color lens on the display plane thereof. Electric wiring of the display device may be passed through a rubber packing on the back of the chassis, for sealing off the inside of the chassis from the outside, while the inside of the chassis is closed. Thus a signal of white light is made.

In some embodiments, a signal of higher reliability can be made by dividing the light emitting devices of the present invention into a plurality of groups and arranging them in a spiral configuration swirling from a center toward outside, while connecting them in parallel. The configuration of swirling from the center toward outside may be either continuous or intermittent. Therefore, desired number of the light emitting diodes and desired number of the sets of light emitting devices can be selected depending on the display area of the display device. This signal is, even when one of the sets of light emitting devices or part of the light emitting devices fail to illuminate due to some trouble, capable of illuminating evenly in a circular configuration without color shift by means of the remaining set of light emitting devices. In some embodiments, the light emitting devices can be arranged more densely near the center, and driven without any different impression from signals employing incandescent lamps.

The foregoing description of the embodiments of this invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the above described invention.

1. A light emitting device comprising:
a light emitting component having an active layer comprising a semi-conductor material;
a phosphor having a general formula Ca₁₊ₓSr₁₋ₓGa_{y}In_{2-y}S_{z}Se_{3-z}F₂, wherein 0≦x≦1, 0≦y≦2 and 0≦z≦3; and
an activator of the phosphor, wherein an emission spectrum of light emitted from the light emitting component excites the phosphor and the activator.

2. The light emitting device of claim 1, wherein the semi-conductor is selected from gallium nitride, indium nitride, aluminum nitride, gallium indium nitride, aluminum gallium nitride and combinations thereof.

3. The light emitting device of claim 1, wherein the activator is selected from the elements of europium (Eu), cerium (Ce), praseodymium (Pr), terbium (Tb), ruthenium (Ru), erbium (Er), manganese (Mn), ionic forms thereof and mixtures thereof.

4. The light emitting device of claim 1, wherein the emission spectrum emitted from light emitting component includes at least one of blue and ultraviolet.

5. The light emitting device of claim 1, wherein the light emitting device is a light emitting diode (LED).

6. The light emitting device of claim 1, wherein the emission spectrum emitted from the light emitting component has a wavelength between approximately 380-500 nm.

7. The light emitting device of claim 1, wherein the phosphor and the activator form an activated phosphor able to absorb part of the emission spectrum having a wavelength between approximately 380-500 nm and said activated phosphor emits a broad emission spectrum having a peak wavelength between approximately 490-650 nm and a tail emission wavelength extending beyond 650 nm.

8. The light emitting device of claim 7, wherein the broad emission spectrum emitted from the activated phosphor and a spectrum of unabsorbed light passed through the activated phosphor from the light emitting component overlap each other to form a continuous combined spectrum.

9. The light emitting device of claim 8, wherein the continuous combined spectrum emits a white color.

10. The light emitting device of claim 1, wherein two or more different phosphors having the general formula Ca₁₊ₓSr₁₋ₓGa_{y}In_{2-y}S_{z}Se_{3-z}F₂ are present.

11. The light emitting device of claim 1 wherein the phosphor is Ca₂Ga₂S₃F₂, CaSrGa₂SSe₂F₂, CaSrGaInSe₃F₂, CaSrGa₂S₃F₂, or Ca₂Ga₂SSe₂F₂.

12. The light emitting device of claim 1, wherein the activator is present in an amount in a range of approximately 0.001 mol % to about 10 mol %.

13. A method for emitting white colored light from a light emitting device comprising the steps of:
providing the light emitting device having a light emitting component with an active layer comprising a semi-conductor material;
emitting a blue or ultraviolet light from the light emitting component;
providing a phosphor having a general formula Ca₁₊ₓSr₁₋ₓGa_{y}In_{2-y}S_{z}Se_{3-z}F₂, wherein 0≦x≦1, 0≦y≦2 and 0≦z≦3;
activating the phosphor with an activator selected from the group consisting of elemental forms of europium (Eu), cerium (Ce), praseodymium (Pr), terbium (Tb), ruthenium (Ru), erbium (Er), manganese (Mn), ionic forms thereof and mixtures thereof;
absorbing part of the blue or ultraviolet light by the activated phosphor; and
emitting from the activated phosphor a spectrum of light that provides white light.

14. The method of claim 13, wherein the semi-conductor material is selected from the group consisting of gallium nitride, indium nitride, aluminum nitride, gallium indium nitride, aluminum gallium nitride and combinations thereof.

15. The method of claim 13, wherein the light emitting device is a light emitting diode (LED).

16. The method of claim 13, wherein the step of emitting the blue or ultraviolet light produces an emission spectrum having a wavelength between approximately 380-500 nm.

17. The method of claim 13, wherein the step of emitting from the activated phosphor a spectrum of light that provides white light, produces a broad emission spectrum having a peak wavelength between 490-650 nm and a tail emission wavelength extending beyond 650 nm.

18. The method of claim 17, wherein the broad emission spectrum emitted from the activated phosphor and a spectrum of unabsorbed light passed through the activated phosphor from the light emitting component, overlap each other to form a continuous combined spectrum.

19. The method of claim 13, wherein the phosphor is selected from the group consisting of Ca₂Ga₂S₃F₂, CaSrGa₂SSe₂F₂, CaSrGaInSe₃F₂, CaSrGa₂S₃F₂, Ca₂Ga₂SSe₂F₂ and mixtures thereof.

20. The method of claim 13, wherein europium (Eu), cerium (Ce), praseodymium (Pr), terbium (Tb), ruthenium (Ru), erbium (Er), manganese (Mn) and mixtures thereof are present in a range of approximately 0.001 mol % to about 10 mol %.
